(19) United States
(12) Patent Application Publication
(10) Pub. No.: US 2016/0080778 A1
(43) Pub. Date: Mar. 17, 2016

(54) HYBRID MODULATOR UTILIZING DIGITAL DOMAIN MULTIPLEXING

(71) Applicant: GATESAIR, INC., Mason, OH (US)

(72) Inventors: Stefan ILSEN, Braunschweig (DE); Daniel ROTHER, Hannover (DE)

(21) Appl. No.: 14/484,096

(22) Filed: Sep. 11, 2014

(51) Int. Cl. H04N 21/2389; H04N 21/643; H04N 21/41; H03M 1/66

(52) U.S. Cl. CPC H04N 21/2389; H03M 1/662; H04N 21/643; H04N 21/4126

(57) ABSTRACT

Systems and methods are provided for generating a hybrid signal. A first signal source is configured to provide a first digital signal having a first sample rate, and a second signal source is configured to provide a second digital signal having a second sample rate. A resampling component is configured to resample the second digital signal into a resampled signal having the first sample rate. A multiplexing component is configured to combine the first digital signal and the resampled signal into a multiplexed signal. A digital-to-analog converter is configured to convert the multiplexed signal into an analog signal.

### TECHNICAL FIELD

The present invention relates to an apparatus and method for broadcasting radio frequency signals, and more specifically, to a hybrid time-divisional multiplexing modulation schema.

### BACKGROUND OF THE INVENTION

A wireless system, such as a digital video broadcasting system, may transmit data in the form of a sequence of frames arranged in a frame structure. For example, a digital video broadcasting system can utilize any of a Digital Video Broadcasting (DVB) standard, an Advanced Televisions Systems Committee (ATSC) standard, an Integrated Services Digital Broadcasting (ISDB) standard, or Digital Multimedia Broadcasting (DMB) standard. Each frame typically includes a preamble section and a data section. The preamble section and the data section are time-multiplexed.

### SUMMARY OF THE INVENTION

In accordance with one aspect of the present invention, a hybrid modulator system is provided. A first signal source is configured to provide a first digital signal having a first sample rate, and a second signal source is configured to provide a second digital signal having a second sample rate. A resampling component is configured to resample the first digital signal into a resampled signal having a third sample rate. A multiplexing component is configured to combine the first digital signal and the resampled signal into a multiplexed signal. A digital-to-analog converter operates at the third sample rate and is configured to convert the multiplexed signal into an analog signal.

In accordance with another aspect of the present invention, a method is provided for generating a hybrid signal. A first digital signal having a first sample rate is generated. A second digital signal having a second sample rate that is different from the first sample rate is generated. The second digital signal is resampled to provide a resampled signal having a sample rate equal to the first sample rate. The first digital signal and the resampled signal are resampled to provide a multiplexed signal. The multiplexed signal is converted to an analog signal.

In an embodiment of the present invention, a method is provided for generating a hybrid signal. A first digital signal having a first sample rate is generated. A second digital signal having a second sample rate that is different from the first sample rate is generated. The first digital signal is resampled to provide a first resampled signal having a third sample rate that is different from each of the first and second sample rates. The second digital signal is resampled to provide a second resampled signal having the third sample rate. The first resampled signal and the second resampled signal are multiplexed to provide a multiplexed signal. The multiplexed signal is converted to an analog signal.

### BRIEF DESCRIPTION OF THE DRAWINGS

For a better understanding of the invention, reference may be made to the accompanying drawings, in which:

FIG. 1 illustrates a hybrid modulator system for generating a hybrid signal in accordance with an aspect of the present invention;

FIG. 2 illustrates one example of a hybrid modulator system for generating a hybrid signal in accordance with an aspect of the present invention;

FIG. 3 illustrates a method for generating a hybrid signal in accordance with an aspect of the present invention; and

FIG. 4 illustrates another method for generating a hybrid signal in accordance with an aspect of the present invention.

### DESCRIPTION OF EMBODIMENTS

This invention enables the realization of a hybrid modulator as a single device which generates a signal consisting of two independent and unrelated waveform types which are independently generated in their respective native sample rate, enabling the multiplexing of both waveforms in time division multiplexing prior to digital-to-analog conversion. The digital-to-analog converter does not need to be re-configured when switching between waveforms. This allows sharing of one RF channel while using different signal types and transmission devices.

To allow multiple waveform types to be combined and share a single digital-to-analog converter (DAC), the hybrid modulator system described herein resamples at least one of a primary waveform and a secondary waveform, such that the secondary waveform matches a sample rate of the primary waveform. This technique allows the native sample rates of the primary and secondary waveforms to be independent and unrelated. The resulting sample rate can be at baseband or at a higher interpolated rate up to the DAC clock rate. Common sample rate conversion techniques like polyphase filtering or windowed sinc interpolation can be used to perform real-time upsampling using digital signal processing. After the re-sampling is performed, the independent signals can be merged/multiplexed digitally using the resampled rate prior to the digital-to-analog conversion. Since the digital domain is used for multiplexing the arbitrary signals, further digital signal processing techniques can be used on the merged signal. After the sample rate conversion, additional timing and frequency synchronization coordination can be avoided by using the same DAC.

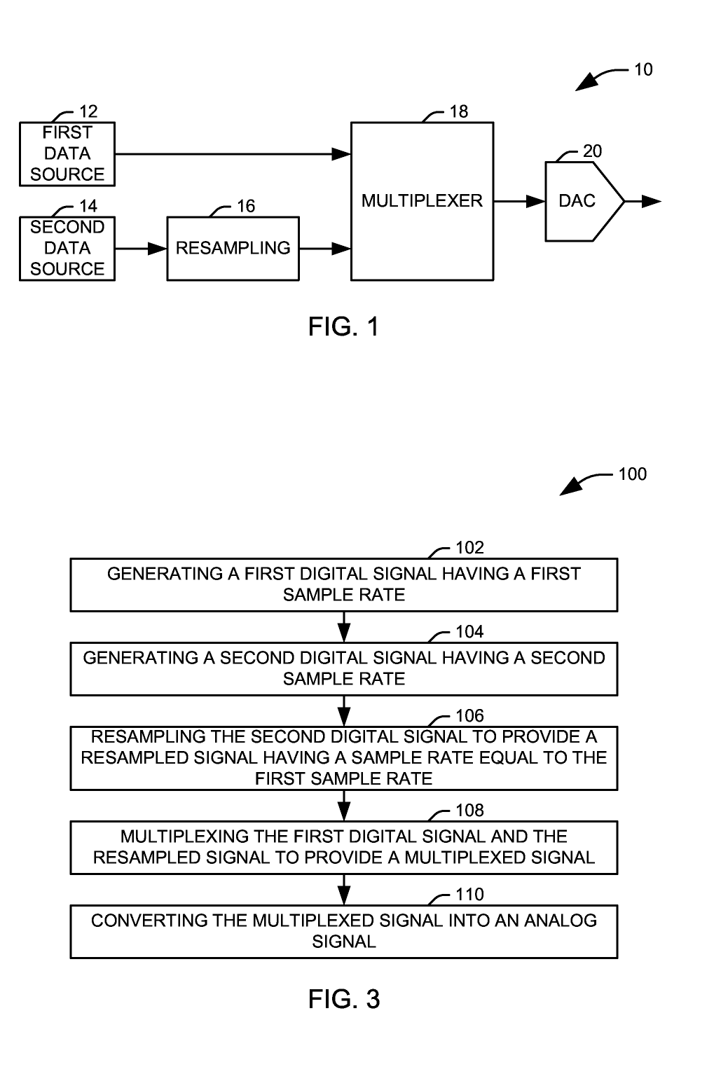

FIG. 1 illustrates a hybrid modulator system 10 for generating a hybrid signal in accordance with an aspect of the present invention. The system 10 includes a first data source 12 configured to provide a digital signal having an associated first sample rate, and a second data source 14 configured to provide a digital signal having an associated second sample rate that is different from the first sample rate. For example, the data sources 12 and 14 can include a modulator configured to encode data into an associated carrier signal or a signal source that directly provides the digital signal, for example, as a baseband signal, without an associated external carrier.

The hybrid modulator system 10 further includes a resampling component 16 that receives the second digital signal and resamples the second digital signal to provide a resampled signal having a third sample rate. For example, the resampling component 16 can utilize polyphase filtering or windowing sinc interpolation for changing the sample rate of the signal. It will be appreciated that the third sample rate can be either of greater than or less than the second sample rate, and the resampling component 16 can be an upsampler or a downsampler. In one implementation, in which mobile data (e.g., LTE data) is inserted into an extension slot associated with a digital video standard, the mobile data can be upsampled to match the sample rate of the digital video, such that the first sample rate is equal to the third sample rate.

A multiplexer 18 combines the first digital signal and the resampled signal according to an associated multiplexing scheme to provide a multiplexed signal. For example, the multiplexer 18 can combine the signals to provide a time, frequency, or code division multiplexed signal. The multiplexed signal is then provided to a digital-to-analog converter (DAC) 20, operating at the third sample rate. In the illustrated embodiment, the third sample rate is equal to the first sample rate, although it will be appreciated that that a second resampling component (not shown) could be provided to resample the first digital signal to the third sample rate prior to multiplexing at the multiplexer 18. Accordingly, the DAC 20 can be operated at an arbitrary sample rate, independent of the first and second sample rates.

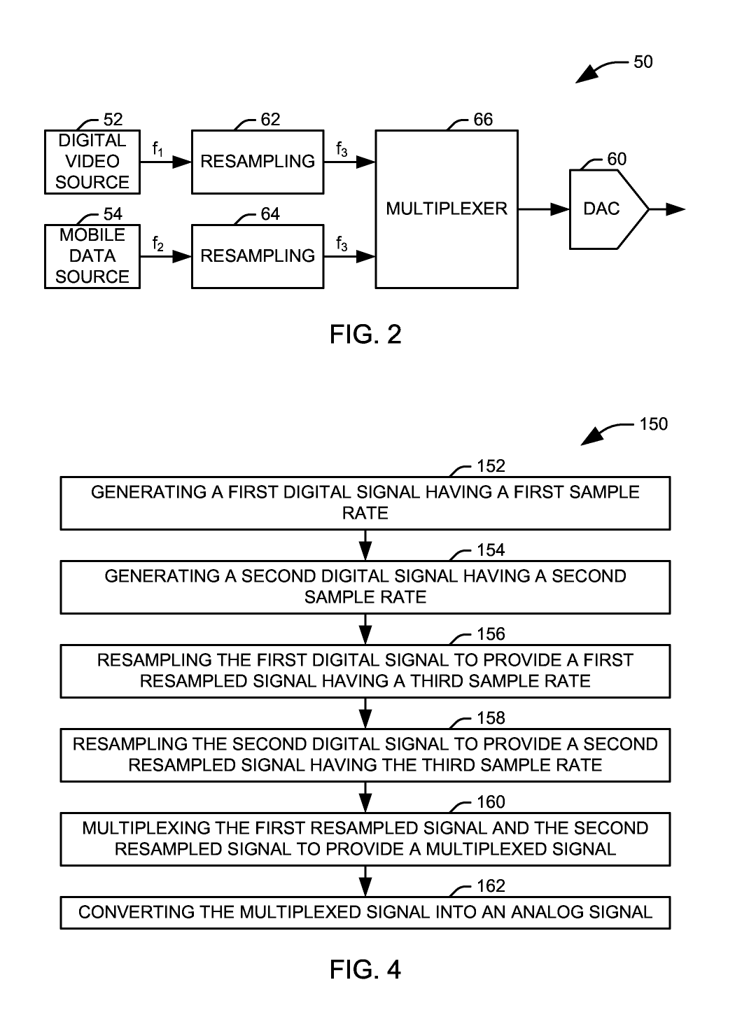

FIG. 2 illustrates one example of a hybrid modulator system 50 for generating a hybrid signal in accordance with an aspect of the present invention. In the illustrated implementation, the system 50 is part of a tower overlay arrangement to provide mobile data in combination with terrestrial broadcasting. Some terrestrial broadcasting standards provide frame structures with slots for carrying video, as well additional slots for other data. For example, the DVB Terrestrial 2nd generation (DVB-T2) standard for terrestrial standard broadcasting has a super frame structure consisting of a number of frames. A slot, included in the super frame or each frame, does not transmit a DVB-T2 signal. The super frame is referred to as a Future Extension Frame (FEF), and, FEF slots may be provided in addition to the parts of the frame structure which transmit video signals intended for reception by conventional DVB receivers. These additional physical slots, such as the FEF slots, can be used for the transmission of signals, such as, for example, signals intended for reception by handheld receivers.

The system 50 includes a digital video source 52 configured to provide a digital video signal, having a first sample rate, according to a desired video standard. In one implementation, the digital video is provided according to the DVB-T2 standard as a plurality of digital video streams multiplexed into a single digital stream via Coded Orthogonal Frequency Divisional Multiplexing (COFDM). A mobile data source 54 provides mobile data, that is, data formatted for reception at a mobile device at a second sample rate. For example, the mobile data source 54 can provide data formatted according to the Long-Term Evolution (LTE) standard.

In accordance with an aspect of the present invention, each of the digital video and the mobile data are resampled to a third sample rate associated with a digital-to-analog converter 60 used to convert the signal to an analog signal for amplification and broadcast. To this end, the digital video data is provided to a first resampling component 62 that resamples the digital video to the third sample rate, and the mobile data is provided to a second resampling component 64 that resamples the mobile data to the third sample rate. In one implementation, the third sample rate is intermediate between the first and second sample rates, with the digital video signal being downsampled and the mobile data being upsampled. It will be appreciated, however, that the third sample rate is effectively arbitrary and can be either higher or lower than both of the first sample rate and the second sample rate.

The resampled digital video data and mobile data are provided to a multiplexer 60 to combine the data into a single digital signal compliant with the DVB-T2 standard. For example, the mobile data can be inserted into a future extension slot of the DVB-T2 signal. By performing the signal multiplexing in the digital domain, it will be appreciated that digital signal processing techniques can be applied to the multiplexed signal. The multiplexed data is then provided to the digital-to-analog converter 60 where it is transformed into an analog signal for amplification and broadcast.

In view of the foregoing structural and functional features described above, a method in accordance with various aspects of the present invention will be better appreciated with reference to FIGS. 3 and 4. While, for purposes of simplicity of explanation, the method of FIGS. 3 and 4 are shown and described as executing serially, it is to be understood and appreciated that the present invention is not limited by the illustrated order, as some aspects could, in accordance with the present invention, occur in different orders and/or concurrently with other aspects from that shown and described herein. Moreover, not all illustrated features may be required to implement a method in accordance with an aspect the present invention.

FIG. 3 illustrates a method 100 for generating a hybrid signal in accordance with an aspect of the present invention. At 102, a first digital signal having a first sample rate is generated. For example, the first digital signal can be digital video data in a DVB-T2 format. At 104, a second digital signal having a second sample rate that is different from the first sample rate is generated. For example, the second digital signal can be mobile data compliant with a long term evolution (LTE) standard. It will be appreciated that the second sample rate can be greater than or less than the first sample rate.

At 106, the second digital signal is resampled to provide a resampled signal having a sample rate equal to the first sample rate. For example, polyphase filtering or windowing sinc interpolation can be applied to the second digital signal to resample the signal to the desired sample rate. At 108, the first digital signal and the resampled signal are multiplexed to provide a multiplexed signal. It will be appreciated that the multiplexing can be any appropriate multiplexing algorithm, such as time-division multiplexing, frequency-division multiplexing, or code-division multiplexing. At 110, the multiplexed signal is converted to an analog signal. For example, the signal can be converted via a digital-to-analog converter operating at the third sample rate.

FIG. 4 illustrates another method 150 for generating a hybrid signal in accordance with an aspect of the present invention. At 152, a first digital signal having a first sample rate is generated. For example, the first digital signal can be digital video data in a DVB-T2 format. At 154, a second digital signal having a second sample rate that is different from the first sample rate is generated. For example, the second digital signal can be mobile data compliant with a long term evolution (LTE) standard. t 156, the first digital signal is resampled to provide a first resampled signal having a third sample rate that is different from each of the first sample rate and the second sample rate. For example, polyphase filtering or windowing sinc interpolation can be applied to the second digital signal to resample the signal to the desired sample rate. It will be appreciated that the third sample rate can be less than both of the first and second sample rates, greater than both of the first and second sample rates, or between the first and second sample rates.

At 158, the second digital signal is resampled to provide a second resampled signal having the third sample rate. At 160, the first digital signal and the resampled signal are multiplexed to provide a multiplexed signal. It will be appreciated that the multiplexing can be any appropriate multiplexing algorithm, such as time-division multiplexing, frequency-division multiplexing, or code-division multiplexing. At 162, the multiplexed signal is converted to an analog signal. For example, the signal can be converted via a digital-to-analog converter operating at the third sample rate.

What have been described above are examples of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications, and variations that fall within the scope of the appended claims.

Having described the invention, we claim:

1. A hybrid modulator system comprising:
a first signal source configured to provide a first digital signal having a first sample rate;
a second signal source configured to provide a second digital signal having a second sample rate;
a resampling component configured to resample the first digital signal into a resampled signal having a third sample rate;
a multiplexing component configured to combine the first digital signal and the resampled signal into a multiplexed signal; and
a digital-to-analog converter operating at the third sample rate and configured to convert the multiplexed signal into an analog signal.

2. The system of claim 1, wherein the resampling component is a first resampling component and the resampled signal is a first resampled signal, the system further comprising a second resampling component configured to resample the second digital signal into a second resampled signal having the third sample rate.

3. The system of claim 1, wherein the first sample rate is equal to the third resampling component.

4. The system of claim 1, wherein the third sample rate is greater than the first sample rate and the resampling component is configured to upsample the first digital signal.

5. The system of claim 1, wherein the third sample rate is less than the first sample rate and the resampling component is configured to downsample the first digital signal.

6. The system of claim 1, wherein the multiplexing component is configured to combine the first digital signal and the resampled signal into a time-division multiplexed signal.

7. The system of claim 1, wherein the multiplexing component is configured to combine the first digital signal and the resampled signal into a frequency-division multiplexed signal.

8. The system of claim 1, wherein the resampling component applies one of polyphase filtering and windowing sinc interpolation to the first digital signal.

9. The system of claim 1, wherein the second signal source is a modulator configured to encode digital video data compliant with the DVB-T2 standard onto an associated carrier and the first signal source provides mobile data formatted for reception at a mobile device compliant with a long term evolution (LTE) standard.

10. The system of claim 9, wherein the third sample rate is equal to the second sample rate, such that the mobile data is resampled to the sample rate associated with the digital video data.

11. The system of claim 9, wherein the resampling component is a first resampling component and the resampled signal is a first resampled signal, the system further comprising a second resampling component configured to resample the digital video data into a second resampled signal having the third sample rate.

12. A method for generating a hybrid signal comprising:
generating a first digital signal having a first sample rate;
generating a second digital signal having a second sample rate that is different from the first sample rate;
resampling the second digital signal to provide a resampled signal having a sample rate equal to the first sample rate;
multiplexing the first digital signal and the resampled signal to provide a multiplexed signal; and
converting the multiplexed signal to an analog signal.

13. The method of claim 12, wherein generating a first digital signal having a first sample rate comprises generating digital video data in a DVB-T2 format and generating a second digital signal comprises generating mobile data compliant with a long term evolution (LTE) standard.

14. The method of claim 13, wherein resampling the second digital signal to provide a resampled signal having a sample rate equal to the first sample rate comprises upsampling the mobile data to the first sample rate.

15. The method of claim 13, wherein multiplexing the first digital signal and the resampled signal to provide a multiplexed signal comprises applying time division multiplexing to the digital video and the mobile data.

16. A method for generating a hybrid signal comprising:
generating a first digital signal having a first sample rate;
generating a second digital signal having a second sample rate that is different from the first sample rate;
resampling the first digital signal to provide a first resampled signal having a third sample rate that is different from each of the first and second sample rates.
resampling the second digital signal to provide a second resampled signal having the third sample rate;
multiplexing the first resampled signal and the second resampled signal to provide a multiplexed signal; and
converting the multiplexed signal to an analog signal.

17. The method of claim 16, wherein the third sample rate is greater than each of the first sample rate and the second sample rate.

18. The method of claim 16, wherein the third sample rate is less than each of the first sample rate and the second sample rate.

19. The method of claim 16, wherein the third sample rate is greater than one of the first sample rate and the second sample rate and less than an other of the first sample rate and the second sample rate.

20. The method of claim 16, wherein generating a first digital signal having a first sample rate comprises generating digital video in a DVB-T2 format and generating a second digital signal comprises generating mobile data compliant with a long term evolution (LTE) standard.
